(19) United States
(12) Patent Application Publication
(10) Pub. No.: US 2009/0314529 A1
(43) Pub. Date: Dec. 24, 2009

(54) AQUEOUS PRINTABLE ELECTRICAL CONDUCTORS (XINK)

(76) Inventors: Michael Petersen, Rockcliffe Park (CA); Mykola Sherstyuk, Ottawa (CA); Dan Tonchev, Ottawa (CA); Colin Dwarika, Ottawa (CA)

Correspondence Address: Henkel Corporation, 10 Finderne Avenue, Bridgewater, NJ, 08807, US

(21) Appl. No.: 12/280,004

(22) PCT Filed: Jun. 8, 2006
(86) PCT No.: PCT/CA2006/000939

§ 371 Date: Mar. 23, 2009

(30) Foreign Application Priority Data
Jun. 9, 2005 (CA) 2,509,608
Nov. 30, 2005 (CA) 2,528,420

(51) Int. Cl. H05K 1/09; C09D 11/10; B05D 5/12

(52) U.S. Cl. 174/257; 252/512; 252/514; 427/99.4; 427/97.6; 427/98.4; 427/97.5

(57) ABSTRACT

An aqueous printable electrical conductor (APEC) is defined as a dispersion comprising metal powder (with specific surface properties) dispersed into an aqueous acrylic, styrene/acrylic, urethane/acrylic, natural polymers vehicle (gelatine, soy protein, casein, starch or similar) or in a film forming reactive fatty acids mixture without a binder resin. The aqueous printable dispersion can be applied to substrates through different printing processes such as flexography, gravure, screen, dry offset or others. Exemplary substrates include: (1) coated paper, (2) uncoated paper, and (3) a variety of plastics with treated and untreated surfaces. When printed at a thickness of 1-8 μm, heating to cure is not required as the dispersion cures at ambient temperatures. When the dispersion is used for any of the above applications it will provide sufficient electrical conductivity to produce electrical circuits for intelligent and active packaging, sensors, radio frequency identification (RFID) tag antennae, and other electronic applications.

### FIELD OF THE INVENTION

The present invention relates to the preparation of electrical conductors that can be printed on substrates and used as electrical circuits, for example, in intelligent and active packaging, sensors, and RFID antennae. These electrical conductors are identified herein as Aqueous Printable Electrical Conductors or “APECs”.

### BACKGROUND OF THE INVENTION

Printable inks, which can be used in different applications, are known, for example, in U.S. Pat. No. 6,379,745 and in a US Patent Application No. 2003/0151028. These inks, however, have limitations. The printable electrical conductive materials of the '745 patent are not aqueous and the substrates with which such inks are used are generally limited to plastics, which are heat resistant and are not recyclable. The materials of the '028 patent application cannot achieve the desired degree of conductivity for the applications described herein, and they are not printable on plastics. Moreover, neither reference describes how to provide a commercially viable means to ensure adequate electrical conductivity using an aqueous media combined with ambient temperature air curing, resulting in the production of industry-useable devices on a number of existing printing press set-ups common in world markets.

Other patents, such as U.S. Pat. Nos. 5,492,653; 5,286,415; and 4,715,989 describe aqueous silver-, other metallic-, and carbon flakes-based compositions, as well as water-based conductive thick film inks that are mostly used as coating compositions, with primary applications being sprays, paints or printable screens. They are always used with organic co-solvents.

### SUMMARY OF THE INVENTION

The present invention is a process for the manufacture of a conductive coating material for application to a substrate, comprising the steps of: a) providing an aqueous polymeric emulsion; b) dispersing into the aqueous polymeric emulsion at least 80% by weight on a solids basis of a conductive metal powder; c) mixing the polymeric emulsion and conductive metal powder until homogeneous to form a conductive coating ink; and d) adding an effective amount of base to maintain the ink in a pH range of 7.5 to 10.5. In a further embodiment, the process comprises the additional steps of e) disposing the conductive coating ink onto said substrate; and f) allowing the ink to dry, thereby forming said conductive coating on said substrate.

As used in this specification and in the claims, a conductive powder will be deemed to include metal in both flake and particulate form. The preferred base is NH₄OH, but other bases are acceptable, although the preferred bases will be relatively volatile, as is ammonia.

In one embodiment, the addition of the base can occur before the dispersion of the metal conductive powder. In a further embodiment the base and conductive metal powder are added concurrently.

In another embodiment, the process comprises the additional steps of heating the coated substrate to a temperature no greater than 400° F. (204.4° C.), thereby enhancing conductivity, and/or overcoating the dried conductive coating with an aqueous acid solution having a pH of 1.5 or less and allowing the acid solution to air dry, thereby enhancing conductivity.

In further embodiments, the process comprises disposing the conductive coating ink on a substrate as one or more narrow lines, thereby forming at least one conductive trace on the substrate, or disposing as a film covering at least a portion of a surface of said substrate.

The dispersion comprises powder or flakes of conductive material suspended in an aqueous resin or polymeric vehicle, for example, an acrylic, styrene/acrylic, or urethane/acrylic aqueous dispersion. This dispersion is capable of being deposited onto a substrate using commercial printing methods for production of various devices. The preferred morphology of the conductive material is flaky, although particles of metal may be added to complement the flakes. Average particle size of the metal will range from 0.1 to 15 μm, and in one embodiment ranges from 0.6 to 8 μm. In one embodiment the metal is silver (Ag), or silver-coated copper. The surface of the metal flakes is typically chemically treated by the supplier, usually with one or more fatty acids, but this does not exclude the use of initially untreated flakes, in which case the surface treatment is performed in-house as a first step before preparation of the dispersion.

Compared to conventional printing ink vehicles, the aqueous vehicle used in this invention has lower polymer resin content, the polymer not subject to intensive cross-linking, and very low levels or even no additives, such as, adhesion promoters, antifoaming agents, waxes, and the like. When additives are used, the dispersion may require two to four times more frequent on-press additions of those additives, usually in negligible amounts (less than 1%) compared to conventional printing inks. The metal's surface treatment needs to be selected to promote stability of the metal within the dispersion vehicle system. Metal particles having a very thin layer of low molecular weight fatty acid on their surfaces are preferred, as this ensures that the surface treatment layer does not affect the conductivity significantly. The surface treatment also regulates the surface pressure of the metal particles. Surface treatment substances, such as the fatty acids, help in the film-forming process of the deposited conductor and can be critical to the printability of conductive traces for different applications.

The process of dispersing the metal in the aqueous resin vehicle requires slow mixing. A preferred method is to use a dispersion mixer with specially shaped mixing heads to ensure good visually laminar flow. In contrast, when preparing conventional inks grinding aids and surfactants are added during the mixing process to reduce the surface pressure between mixing surfaces. To avoid possible influences on the conductive properties, such additives preferably are not used in the current process. Generally, the quantity of metal added is two to four (or more) times the weight of the vehicle. As a result of this high load, heat is produced during the mixing process because of friction and increased mixing speed. This is mitigated by regulating the mixing speed and adding small aliquots of the vehicle during mixing. When the metal has been fully incorporated into the vehicle, the dispersion is mixed at a higher speed for a short time with care being taken to avoid introducing air into the mixture, as by cavitation. The temperature of the dispersion should not exceed 30-35° C. during mixing. In some cases, the final product will need to be filtered using an appropriate sized silk mesh filter. The mixing process produces a visually homogeneous mixture in liquid form that is stored in sealed bottles at ambient and room temperature (5° C. to 30° C.).

The viscosity of the APECs varies directly with the metal load. As an example, for flexography printing applications, the viscosity should range from 25 to 85 seconds measured with a Zahn 3 cup (approximately 500 to 3600 centipoises, based on the APEC's specific gravity of 2.4-4). Gravure, screen, and some other dry offset printing processes can be achieved by adjusting the viscosity of the base composition.

The viscosity and printing properties of APECs should be adjusted prior to printing on the press and held constant during printing through the appropriate use of additives. This can be achieved by adding ammonia water and minimal amounts of specially selected antifoaming agents if needed. Depending on the printing method and duration of the print run, the addition of 1.0-10% NH₄OH (ammonia water) and 0.01-0.2% antifoaming agent (both by volume) may be necessary. Such addition should be done immediately prior to printing and the combination mixed well. The amounts and frequency of later additions are dependent on the ink properties, structure of the press, exposed surfaces of the emulsion, ambient temperature, humidity, printing speed and other factors. Closed ink recirculation systems, coupled to a slow ink circulating pump, are best for keeping the physical properties of the printed electronic conductors constant.

### DETAILED DESCRIPTION OF THE INVENTION

Generally speaking, the present invention provides a process for the preparation of aqueous printable electrical conductors (APECs), which process involves the selection of appropriate ingredients and the mixing of those ingredients together in order to achieve a composition that can be utilized with existing, commercially available printing presses for the printing of electrically conductive traces on a variety of substrates. In the preferred embodiments conductivity is achieved through the use of fine flakes of metallic silver or silver-coated copper suitably mixed in an aqueous polymer emulsion, with the resulting dispersion being available for use in a printing press.

The conductivity of APECs in use depends on a number of factors. The most important is the position, arrangement, and physical connections among the powder or flake metal particles within the dispersion that is deposited onto the substrate. Conductivity and stability are influenced by the film drying process, the application or operation of heating/curing media, and external treatment processes such as acid wash, applied pressure, and high energy light treatments.

It is desirable to achieve proper orientation and close positioning among the metal particles without the formation of a thick polymer particle surface-wetting layer. This is accomplished by selection of raw materials and correct preparation of the vehicle. It is also beneficial to prepare the mixing surface through the use of techniques such as particle surface treatment.

The proper orientation of the particles is facilitated by surface property adjusters, including, but not limited to, (1) surfactants, (2) adhesion promoters, and (3) stabilizers. These chemicals generally result in good particle wetting and stability. However, when used injudiciously, they also cause a stable dielectric surface layer to form on top of the particles (metal particles in the present case) thereby decreasing electrical conductivity. A trade-off thus exists when using surface property adjusters. For these additives to be used successfully, they must be highly efficient and work in extremely low quantities. It is also preferable to use non-ionic stabilizers to reduce the forces acting on the particle surface layers. There also is an advantage from the aqueous media, which allows for the elimination of the electrical charges resulting from friction created by the mixing process, thereby allowing better orientation. A suitable degree of particle wetting can be achieved in some instances by shaking. Shaking is limited to small volumes and is not necessarily scalable for commercial serial printing.

Thin surface layers on the metal particles are required for an acceptably long commercial shelf life. With the current process, shelf lives of several months (e.g. greater than 6 months) are achieved. Incompatibility exists, however, between ammonia water or any water media and the fatty acids coating the metal particles. This incompatibility prevents the metal particles from being completely stable. To achieve the greatest conductive properties, the metal particles must not be permanently wetted within the vehicle polymer layers.

The formation of a polymer layer on top of metal particle surfaces is desirable to achieve proper particle deposition during the printing process. The polymer layer also facilitates adherence of the particles to the substrate material, and enhances inter-particle consolidation after the drying process.

APECs tend to dry quickly after printing because of the low percentage of liquid in the metal dispersion. The pH of the APEC is adjusted typically to a pH in the range of 7.5 to 10.5; in another embodiment, to a pH in the range of 8 to 10; and in a further embodiment, to a pH in the range of 9 to 9.5. In one embodiment within these ranges, the pH is initially at 7.5 to 8.5 and as within all ranges drops when the ammonia water evaporates. During this process the polymer system goes from a water-soluble state to a water-insoluble state. The drying process can be facilitated by forced convection with ambient or slightly elevated temperature air. This process plays a major role in determining the conductive properties of the final product. While the APEC is drying the polymers shrink. This occurs when the polymers lose their water bridges, which are composed of hydrogen bond chemical connections.

The post printing drying process continues for 24 hours at ambient temperature, until most of the liquid has evaporated. This results in a conductivity increase of up to 50 percent during drying. Furthermore, several sub-processes take place during the drying process. For example, oxidative polymerization may result in the formation of oxygen cross-linking bridges. Other sub-processes are characterized by additional cross-linking of bonds between the reactive polymer chains in the vehicle. Further cross-linking of bonds results from Diels-Alder reactions, but only when conjugated double bond structures exist within the vehicle system.

The final aspect of chemical drying results in a significantly reduced volume of the printed conductive coating ink, which affects coating thickness and metal particle orientation. The metal particles move closer to each other due to the reduced volume of the printed coating. At the same time, more cross-linked polymers increase the dielectric properties, thereby decreasing conductivity. The greatest effect, however, is due to the orientation of the metal particles, resulting in an overall increase in conductivity. Post-drying or post-drying under pressure gives increased conductivity, resulting in stable resistance readings and a conductive coating that is less dependent on ambient temperature and humidity. These post-printing operations are optional.

Normally, with flexographic printing, APECs do not require special heating. Room temperature blown air is enough to obtain usable prints. However, with gravure and screen printing, APECs require extra heat for thorough curing and better performance, especially when materials of differing viscosities are used in the printing process.

In one embodiment, heating and curing methods employ IR heat sources that have the ability to deliver energy into the printed layer allowing drying to commence not from the surface (as is the case when using hot air to dry) but from within. Although these APECs are not UV curable, application of UV drying during flexographic printing offers two benefits: (1) UV sources produce additional heat, and (2) UV light leads to a slight destruction of binder polymers, which increases electrical conductivity.

In a further embodiment, an ink can be made as described herein, either without, or with only a minimal amount of, binder resin, and an 80-100% water emulsion of pre-reacted fatty acids with a metal salt, including the metal salts of Ag, Pd, Pt, Au, Cr, Ni, Cu, Na, K, and Mg, to form a metal soap and corresponding surfactant. Using Ag as an example, the reaction is:

CH₃(CH₂)₇CH═CH(CH₂)₇COOH+AgCl═CH₃(CH₂)₇CH═CH(CH₂)₇COOAg+HCl

This ink is then subjected to a high energy treatment, for example, thermal shock at 200° C. for 1-3 seconds, to destroy the fatty acid chains and release the metal to form a nano dispersion. Nano dispersed metals (Ag in the example) create conductive bridges between the silver flakes, thus increasing the conductivity of the printed traces. A further benefit of this process is that some acid, in this case hydrochloric acid (HCl), is released. The acid reduces the pH, which helps keep the polymer at low viscosity at the same solids content.

A major advantage of APECs is their ability to be printed on paper substrates. Pricing benefits (compared to printing applications requiring other substrates) and ecological gains (via de-inking procedures and recycling benefits) are other advantages of APECs.

### EXAMPLES

### Example 1

### APEC Conductive Coating Ink Formulated for Flexography to Print UHF Antennae

Predominantly oleic fatty acid treated silver (particle size 1 to 5 μm flakes shaped) was combined and blended in a regular open air mixer with aqueous solution of 38% solids acrylic resins in water (with ammonia traces to maintain the pH in the range of 7.5-8.5) in a proportion 3.4 to 1 weight portions with no additives. After 20 minutes mixing with an average mixing speed of 1500 rpm with Hi-Vane mixing head (which does not allow the heat to exceed 30° C.) 10% pure ammonia preliminary diluted in water was added via continuous mixing in 1.7 wt. % to the ink. The dispersion was mixed for 5 more minutes. Oleic fatty acids react with ammonia to form ammonia soap according to the following basic chemical reaction:

CH₃(CH₂)₇CH═CH(CH₂)₇COOH+NH₄OH═CH₃(CH₂)₇CH═CH(CH₂)₇COONH₄+H₂O

The reaction is similar for other oils included with oleic acid—linolic and linoleic acids respectively with two and three double bonds. Unsaturated two- and three-double bond fatty acids are responsible for the formation of an elastic film after printing and oleic acid does not dry at all. Oleic acid forms a nano layer on the top of the metal particles, helping to make the silver flakes compatible with alkyl resins added to dispersions to provide stability and printability. Such oleic acid nano layers reduce the conductivity of the APEC; however, when oleic acid is removed from the surface during exposure to heat shock or other drying methods the printed conductive coating will exhibit an increase in sheet conductivity.

The obtained ammonia soap is an active surfactant, which helps achieve partial wetting of the silver particles by washing part of the fatty acid coating off the surface of the metallic flake particles. The reaction essentially produces a lubricant that eases mixing.

Further, when acrylic resins with acid groups are used, the ammonia serves to regulate viscosity, allowing adjustment of pH and drying time, and thus contributing to final conductivity.

A freshly prepared dispersion of the APEC was printed on semi-gloss paper and the resulting prints tested for conductivity, printing properties, adhesion, and other properties, with the following results:

Before any heat treatment the measured sheet resistance was 0.4 Ohms/square on a fresh printed sample (3-4 μm thick films) and decreased to 0.2 Ohms/square over the following 24 hours. After a heat shock was applied the sheet resistance decreased by 100% to less than 0.1 Ohms/square at the same thickness.

To print UHF RFID antenna patterns using the APEC described in this example, a Mark'Andy™ 2200 flexography press is used with 13 BCM Praxair™ anilox drum to print by flexography method with Du Pont™ Cyril photopolymer plates (hardness 42) at speeds up to 350 feet (106.68 meters) per minute with preliminary addition of 0.01% antifoam just before the press starts printing. The results were kept stable with the addition of ammonia water to re-establish the initial volume every 20 minutes. Stable in-line conductivity values are verified with a proprietary high-speed in-line resistance feedback device. This process results in fully working RFID transponder labels made in-line on a standard flexographic press with a chip attachment device, using chips from Texas Instruments and Alien Technologies. The transponders provide read ranges of 14-25 feet.

### Example 2

### APEC Formulated as an Ink for Flexography to Print Smart Packages

Predominantly oleic fatty acid treated silver (particle size 1 to 5 μm flakes shaped) was combined and blended in a regular open air mixer with aqueous solution of 38% solids acrylic resin water emulsion in a proportion 2.4 to 1 by weight with 0.1% polyethylene-/polypropylene wax, a silicon based adhesion promoter 1%, an antioxidant 0.1% and antifoam 0.01%. A plasticizer was added at half the minimal amount recommended by the manufacturer.

The above blend was mixed at an average speed of 1500 rpm with a Hi-Vane mixing head (which does not allow the heat to exceed 30° C.), and resulted in an APEC, which was stored at ambient temperature for six months with no loss in performance.

Fatty acids react with ammonia to form ammonia soaps as described in Example 1. No additional ammonia was added, but ammonia was added on the press to recover the initial volume. The initial ammonia comes from the ammonia existing in the pH adjuster of the acrylic resins. Unsaturated two- and three-double bond fatty acids are responsible for the formation of an elastic film after the printing. There is no requirement for special heating above room temperature blown air. If prolonged extra heat is applied the unsaturated fatty acids polymerize to form a thin dielectric layer on top of the prints, reducing conductivity. If reduction of resistance is desirable a combination of IR, UV and/or heat shock (typically for a few seconds) can be used. However this must be applied under strict control to avoid the opposite effect of the heat treatment, which can release dielectric compounds into the APEC structure and increase resistance.

The small amount of ammonia soap behaves as an active surfactant that lubricates surfaces to ease mixing and improve printability. The presence of the ammonia served to adjust pH and drying time and contribute to the final conductivity.

A dispersion of the APEC was printed on label stock 55 Cast Gloss Elite (Avery Denison) and the prints tested for conductivity. The measured sheet resistance was 1.5-2 Ohms/square on a fresh printed sample (1-2 μm thick films) and this decreased over the subsequent 24 hours to 0.8-1.0 Ohms/square.

### Example 3

### APEC Obtained by Surface Treatment of Printed Films with Acid Solutions

An APEC printing ink was formulated and printed according to Example 2 on a non-PET substrate. Immediately after the printing the printed surface was treated on-line with 1N HCl by touching the surface with an acid-soaked soft drum. The residual acid from the surface was immediately thereafter removed by wiping in-line with a soft absorbing fabric covered drum. The conductivity increased up to 100%. The basic reaction on the surface of the silver flakes is: R—COOAg+HCl═R—COOH+AgCl, where R is any of the fatty acids reacted on the Ag surface (oleic, palmitoleic, etc.). An additional effect of acid surface treatment is surface weakening of the top of the printed film by surface destruction of the dry polymer layer. The surface was dried immediately after treatment by passing the PET through hot metal drums that also are arranged in-line (eg. heat shock as described above). This increased the conductivity by an extra 30 to 50%.

### Example 4

### Industrial Formulation of Ink

This is an example of a process for preparing a material that is acceptable as an electrically conductive antenna for printing to a paper or cardboard substrate. The volumes and weights indicated will be suitable for an extensive printing run, noting that antenna traces can be extremely thin and/or narrow, requiring very small quantities for printing purposes. The quantities of ingredients can be scaled upwards or downwards depending on the volume of printing ink that will be required for the printing run. The steps used to formulate the material are as follows:

1. Set-up a Ross Mixer with a 2″ Cowles blade.
2. Fill a 2.5 L plastic container, of known weight, with approximately 4 kg of silver flake.
3. Weigh 799.2 g of aqueous acrylic polymer emulsion at 38 weight % solids, into a separate 2 L plastic container, the “Mixing Vessel”.
4. (This step is optional and is used when the production batches are large. If batches are not large, no resin is set aside for use as extender, but instead is completely added in step 3.) Weigh 88.8 g of the acrylic polymer emulsion into a smaller plastic bottle, label as “Extender”, seal firmly with a lid, set aside for later use. This amount is 10% by weight of the total acrylic polymer emulsion used.
5. Put the Mixing Vessel onto the Ross Mixer and begin mixing at 500 rpm. Ensure that the Cowles blade is covered by the acrylic polymer emulsion.
6. Commence timing.
7. At one minute, begin adding silver flake to the Mixing Vessel. (NB: do not ‘dump’ the silver into the Mixing Vessel; shake the silver flake over the top of the acrylic emulsion.) If needed, raise the blades to quicken the silver mixing.
8. All of the silver flake should be added over the course of the next 10-15 minutes.
9. Once all the silver flake has been added, lower the blades to a position close to the bottom of the Mixing Vessel. Increase the blade speed to 900 rpm. At this point, a mixing vortex should be created. Raise the blade to create a bigger mixing vortex but do not raise the blade high enough expose it at any point of the mixing process (i.e. avoid cavitation).
10. After 2 minutes mixing at 900 rpm, increase the blade speed to 1,000 rpm.
11. After 2 minutes mixing at 1,000 rpm, increase the blade speed to 1,100 rpm.
12. After 2 minutes mixing at 1,100 rpm, increase the blade speed to 1,200 rpm.
13. (This step is optional and is used only when the batch is large and acrylic emulsion has been reserved and not used completely in step 3.) After all silver flake has been incorporated and the blade speed has reached 1,200 rpm, slowly begin to add Extender. Add this Extender as close to the middle of the mixing vortex as possible. Continue to slowly add the Extender until it is completely added into the ink. This process should take 2-3 minutes.
14. After all Extender is added, slowly add in 117.2 mL of 2.8% NH₄OH to the Mixing Vessel. This process should take two-three minutes. Mix at 1,200 rpm for one additional hour.
15. Approaching the one hour mark, slowly decrease the blade speed over a period of one minute from its current speed down to 500 rpm. Stop the blades when the speed is 500 rpm. Measure the pH, and the viscosity by timing the number of seconds the ink takes to pour through the Zahn 3 cup (ensure that ink has had sufficient time to cool to room temperature before measuring the viscosity).

The above steps were performed as outlined and resulted in an ink having a measured pH of 9.53 and a measured viscosity of 41 sec. Zahn cup no. 3.

16. Dispose the conductive coating on a substrate and allow it to air dry 24-48 hours to achieve stable electrical conductivity. Chips, straps etc, can be applied before electrical conductivity has stabilized as the conductive coating is dry to the touch after one to two seconds.

### Example 5

This Example shows the effect of adding 2.8% NH₄OH to silver loaded conductive inks to achieve a printable viscosity (optimal range 30-60 seconds). A quantity of ink was prepared generally in accordance with the above-identified procedure for preparing a commercially viable volume, except that the weight of silver flakes with respect to the total weight of solids was varied. The volume of NH₄OH added in step 16 likewise was varied, and the resulting pH and viscosity measured and reported. The sheet resistance was measured and recorded after the ink dried.

The variations and results are presented below in Table 1.

TABLE 1
RESULTS FROM VARIOUS ADDITIONS OF 2.8%
(V/W) NH₄OH ON VARIOUS SILVER LOADINGS

| | Average | % v/w | | |
|---|---|---|---|---|
| | Sheet | of 2.8% | | |
| | Resistance | NH₄OH | | Viscosity, Zahn 3 Cup at |
| | (mohms/sq) | added | pH | Room Temp. |
| 87.9% Ag | 193 | 0 | 9.05 | Too thick for the Zahn Cup |
| wt. Per | 184 | 1.5 | 9.15 | 47 sec |
| total | 178 | 3 | 9.27 | 27 sec |
| solids | 190 | 4.5 | 9.47 | 22 sec |
| | 221 | 6 | 9.5 | 20 sec |
| 88.3% Ag | 168 | 0 | 9.03 | Too thick for the Zahn Cup |
| wt. Per | 173 | 1.5 | 9.15 | 52 sec |
| total | 166 | 3 | 9.3 | 27 sec |
| solids | 185 | 4.5 | 9.6 | 22 sec |
| | 203 | 6 | 9.5 | 21 sec |
| 89.0% Ag | 163 | 0.0 | 9.03 | Too thick for the Zahn Cup |
| wt. Per | 169 | 1.5 | 9.15 | 1 min 4 sec |
| total | 158 | 3.0 | 9.43 | 33 sec |
| solids | 185 | 4.5 | 9.65 | 26 sec |
| | 193 | 6.0 | 9.54 | 25 sec |
| 89.3% Ag | 169 | 0 | 9.05 | Too thick for the Zahn Cup |
| wt. Per | 193 | 1.5 | 9.2 | 1 min 9 sec |
| total | 147 | 3 | 9.53 | 37 sec |
| solids | 179 | 4.5 | 9.78 | 32 sec |
| | 185 | 6 | 9.49 | 26 sec |
| 89.9% Ag | 209 | 0.0 | 9.03 | Too thick for the Zahn Cup |
| wt. Per | 188 | 1.5 | 9.2 | 1 min 18 sec |
| total | 143 | 3.0 | 9.53 | 41 sec |
| solids | 180 | 4.5 | 9.75 | 28 sec |
| | 188 | 6.0 | 9.79 | 26 sec |

### Example 6

This Example examines the effects of different additives in place of the 2.8% NH₄OH solution. Using the same procedure as above, the 2.8% NH₄OH was replaced with˜˜100% deionized water and with 100% N,N-dimethylethanolamine, independently and in quantities such that the ending viscosity of the ink was approximately the same for all. The results are set out in Table 2 and show that the sheet resistance is lower with the use of NH₄OH.

TABLE 2
Results from Substituting Water and Amine for NH₄OH

| | Average | | | |
|---|---|---|---|---|
| | Sheet | Amount | | |
| | Resistance | added | Viscosity | |
| | (mohms/sq) | (ml) | (seconds) | pH |
| Control - NH₄OH (2.8% solⁿ) | 165 | 7.79 | 47 | 9.35 |
| deionized water (~100%) | 240 | 8.29 | 50 | 8.67 |
| N,N-dimethylethanolamine | 200 | 8.00 | 49 | 10.15 |
| (~100%) | | | | |

### Example 7

This Example shows that post treatment methods can reduce the sheet resistance of printed silver conductive inks. The procedures for the two treatments used, heat shock and acid wash are given here:

Heat Shock Post-treatment:

1. A DrugSeal™ Model DS100 set between 250-300° F.
2. A printed sample of silver conductive ink is sandwiched between two pieces of blank white paper, now referred to as “the sample”.
3. The DrugSeal™ Model DS100 is opened and the sample is placed on the rubber pad. The DrugSeal™ Model DS100 is then quickly closed for 1 second and then opened and the sample is removed.
4. The printed sample is then removed from the two blank sheets of paper and allowed to cool to room temperature before measurements are taken.

Acid Wash Post Treatment

1. Wash the dried conductive ink with an acid (HCl, H₂SO₄, HNO₃, etc), or an acid solution having a pH below 1.5, using a paper towel moistened with the acid, or wash the dried conductive ink on the ink press using an over-coating setup. Allow samples to dry before taking measurements.

These procedures were conducted on various samples and the results, reported in Tables 3 and 4, indicate that after using these post-treatment processes, a 34-58% decrease in sheet resistance is observed.

TABLE 3
Results of different Post-Treatment Processes

| | Average Sheet | Average Sheet | |
|---|---|---|---|
| | Resistance | Resistance | |
| | Before | After | |
| Post treatment | (mohms/sq) | (mohms/sq) | % Change |
| Control | 154 | 155 | 0 |
| Acid Treatment (AT) | 142 | 84 | −41 |
| Heat Shock (HS) | 143 | 95 | −34 |
| AT then HS | 157 | 67 | −58 |

TABLE 4
Results of different Heat Shock-Treatments

| | Average Sheet | Average Sheet | |
|---|---|---|---|
| | Resistance | Resistance | Average |
| | Before | After | % |
| | HS (mohms/sq) | HS (mohms/sq) | Change |
| HS at 150 F. (65.6 C.) | 152.5 | 148.1 | −2.88% |
| HS at 200 F. (93.3 C.) | 165.8 | 148.5 | −10.42% |
| HS at 250 F. (121.1 C.) | 155.6 | 128.2 | −17.64% |
| HS at 300 F. (148.9 C.) | 157.7 | 105.1 | −33.37% |
| HS at 350 F. (176.6 C.) | 161.6 | 92.4 | −42.83% |
| HS at 385 F. (196.1 C.) | 157.8 | 86.6 | −45.14% |

For the experiments in this example, the following observations were made:

1. Once printed on 60 lb semi-gloss paper, the average measured thickness of the ink is between 1-4 microns
2. The silver conductive ink dries to the touch and cures in ambient conditions, 18-23° C.; 0-40% R.H
3. The ink is made with a silver loading in excess of 80% by wt. of total solids. The preferred range is between 86-91% by wt. of total solids.
4. The paper and the printed material both survive at 385° F. It is anticipated that these materials would also survive at 400° F. (204.4° C.).

### Example 9

A conductive ink, formulated according to Example 4 was printed by flexography on semi-gloss paper to form a line 1 mm wide and 190 mm long. The printed coating was allowed to air dry for 24 hours. The dried coating contained 89.9 wt. % silver. The measured end to end resistance was 27.2 Ohms giving a sheet resistance of 143 mOhms/sq. The thickness of the dried conductive coating was measured at three points along the length and the average calculated to be 2.7 microns. From this the volume resistivity was calculated to be approximately 4×10⁻⁵ Ohm.cm.

### Example 10

### Industrial Example

A SOHN™ 4 colour 8 inch flexography label printing press was used with 10 BCM Praxair Art anilox drum to print by flexography method with Du Pont™ Cyril photopolymer plates (hardness 42) at speeds up to 100 feet per minute. Results were kept stable by the addition of extra ink and extender every one hour of printing. A lamination and die cutting station was used in-line to create pharmaceutical smart package inlays with an additional RFID sensor chip attachment. Such printed smart packages are able to record removal of medication doses from a blister package and display the results on a computer screen using an associated RFID reader and software. Similar technology but with different viscosity and resin binders can be used to make gravure, screen, dry offset etc. APECs.

In summary of the foregoing it will be seen that the present invention provides a number of significant advantages and improvements having regard to the known prior art and the general practice of preparing electrically conductive inks for printing on different substrates. Thus the present invention may be seen to encompass the following:

A method for creating aqueous printable electrical conductors (APECs) which includes preparation of a relatively stable dispersion but with intentionally partially-wetted silver flake particles to increase conductivity. To achieve the greatest conductivity, the metal particles should not be permanently wetted within the vehicle polymer layers. The basic chemistry of the process is demonstrated (example 1).

A method for making APECs which includes (as a means to increase the electrical conductivity) a vehicular system using (a) low molecular weight polymers, (b) polymers incapable of intensive cross-linking and (c) other polymer systems that minimize the influence of dielectric binders.

A method for making APECs using ammonia treatment during dispersion preparation and during printing on commercial presses. Although chemically treated flakes (e.g. with fatty acids and salts) are generally known to be incompatible with ammonia, in the proposed method the ammonia is used to create partial silver particle wetting. This is unrelated to the common use of ammonia as a pH and viscosity adjuster for water based printing inks (see example 1).

A method for producing APECs that requires little or no use of additives (e.g. adhesion promoters, antifoaming agents, waxes, etc.) during preparation but which achieves and maintains desirable printing properties including but not limited to mechanical resistance, shelf life, etc. without compromising the conductivity of the deposited electrical conductor.

A method for creating APECs wherein proper orientation and close positioning among the metal particles is achieved without the formation of a thick polymer particle surface-wetting layer. This is accomplished by special selection of raw materials and correct preparation of the vehicle. It is also desirable to prepare the mixing surface through the use of techniques such as particle surface treatment.

A method for making an APEC that cures at ambient temperature with or without air blowing (depending on the printing speed) when printed in the thickness range of 1-8 μm using a flexography process.

A method for creating an APEC suitable for thick film printing (>8 μm) by screen or gravure printing that is cured with a combination of infrared (IR) and ultraviolet (UV) light sources to achieve optimum conductivity. IR drying is more uniform than hot air drying because the process does not start at the surface but from the bulk of the film and UV light sources are also heat sources whereby the UV light leads to destruction of oil films and sometimes of dry polymer chains in the binder, giving increased conductivity.

A method for creating an APEC suitable for application to substrates by different printing processes such as flexography, gravure, screen, or dry offset printing, and to substrates including but not limited to coated paper, uncoated paper, and plastics with treated and untreated surfaces.

A method for making APECs optimized to print on paper substrates and having the highest quality and pricing benefits compared to existing inks and coatings and with ecological gains (via de-inking procedures and recycling benefits).

A method for increasing the conductivity of an APEC by exposing the printed surfaces (preferably on the printed side) to a thermal shock during printing (e.g. by touching the surface for 1 to 3 seconds with a hot metal drum at 120° C.-300° C. mounted on the printing machine). This increases the conductivity of the printed matter more than 50 percent while reducing the film thickness by 25 percent or more depending on the thickness of the initially printed film. Although such shock drying is not necessary to cure thin-film inks (1-8 μm thickness), it can contribute to maximizing the conductivity of the APEC.

A method for increasing the conductivity of an APEC by exposing the printed surfaces to the combined effect of ultrasound and heat to further increase the conductivity of the printed traces.

A method for creating an APEC that facilitates chemical control over the conductive properties by means of selecting the type of fatty acids to treat the particle surface (forming nano layers) and removing these layers partially and in controlled fashion via chemical reactions through soap (surfactant) forming and subsequent suppression of the foam.

A method for creating an APEC that allows increasing the conductivity chemically by means of forming metal soaps of fatty acids that are susceptible to destruction by oxidation and high temperature shock, releasing a metal in nano dimensional form. This process creates extra bridges between silver flakes and increases conductivity.

A nanotechnology for increasing the conductivity of APEC's by forming nanoscale dispersed metals (Ag in the example) to create conductive bridges among the main components (silver flakes).

A method for creating an APEC that leads to conductivity increasing in the range of 20 to 200% by surface treatment of printed films with 0.1 to 10 N(N=normal) concentration of inorganic and/or organic acids, such as sulphuric H₂SO₄, hydrochloric HCl, nitric HNO₃, acetic acid anhydride (CH₃COO)₂O, etc by penetration of the acid through the surface layer of printed films to Ag flakes, chemically replacing the Ag fatty acid soap on the surface of the flakes with AgCl and freeing the surface of the flakes of the dielectric layer to better reveal the Ag conductivity.

While the present invention has been described herein as relating to the creating of aqueous printable electrical conductors for application to a substrate as a thin trace or line, it is clear that the electrically conductive material, or ink, could be applied to the substrate as wider conductive lines or traces, or even as a coating or film. The width and/or thickness of the applied material will depend on the desired end use of the coated or printed substrate.

It is clear that skilled individuals would be capable of altering certain aspects of the invention without departing from the general principles thereof and accordingly the scope of protection to be afforded this invention is to be determined from the scope of the claims appended hereto.

1. A process for the manufacture of a conductive coating ink for application to a substrate, comprising the steps of:
a) providing an aqueous polymeric emulsion;
b) dispersing into the aqueous polymeric emulsion at least 80% by weight on a solids basis of a conductive metal powder;
c) mixing the polymeric emulsion and conductive metal powder until homogeneous to form a conductive coating ink; and
d) adding an effective amount of base to maintain the ink in a pH range of 7.5 to 10.5.

2. The process of claim 1 wherein said aqueous polymeric emulsion is selected from the group consisting of acrylic resins in water, low molecular weight polymers, and aqueous urethane/acrylic mixes.

3. The process of claim 1 or claim 2 wherein said metal powder is dispersed into said aqueous polymeric emulsion to at least 85% by weight on a solids basis.

4. The process of claim 1 or claim 2 wherein said metal powder is dispersed into said aqueous polymeric emulsion to at least 88% by weight on a solids basis.

5. The process of any one of claims 1 to 4 wherein the base is NH₄OH.

6. The process of claim 5 in which NH₄OH is added to the emulsion in an amount effective to maintain the pH in a range of 8 to 10.

7. The process of any one of claim 5 wherein the amount of NH₄OH added to the emulsion is effective to maintain the pH in a range of 9 to 9.5.

8. The process of any one of claims 1 to 5 wherein said metal powder is constituted by silver flakes having an average particle size in the range of 0.6 to 8 μm.

9. The process of any one of claims 1 to 8 wherein said metal powder is treated with a fatty acid prior to being mixed with said emulsion.

10. A process for the manufacture of a conductive coating on a substrate, comprising the steps of:
a) providing an aqueous polymeric emulsion;
b) dispersing into the aqueous polymeric emulsion at least 80% by weight on a solids basis of a conductive metal powder;
c) mixing the polymeric emulsion and conductive metal powder until homogeneous to form a conductive coating ink;
d) adding an effective amount of NH₄OH to maintain the ink in a pH range of 7.5 to 10.5;
e) disposing the conductive coating ink onto said substrate; and
f) allowing the ink to dry, thereby forming said conductive coating on said substrate.

11. The process of claim 10 further comprising the step of heating the coated substrate to a temperature no greater than 400° F. (204.4° C.) to enhance conductivity.

12. The process of claim 10 wherein said drying step is conducted at a temperature of up to 400° F. (204.4° C.).

13. The process of any one of claims 10 to 12 further comprising the step of overcoating the dried conductive coating with an aqueous acid solution having a pH of 1.5 or less and allowing the acid solution to air dry.

14. The process of any one of claims 10 to 13 wherein said conductive coating ink is disposed on said substrate as one or more narrow lines, thereby forming at least one conductive trace on said substrate.

15. The process of any one of claims 10 to 13 wherein said conductive coating ink is disposed on said substrate as a film covering at least a portion of a surface of said substrate.

16. A conductive coating as prepared by the process according to any one of claims 1 to 8 having resistivity less than about 10⁻⁴ Ohm.cm.

17. A substrate coated with a conductive coating as prepared by the process according to any one of claims 10 to 15.
